(19) United States
(12) Patent Application Publication
(10) Pub. No.: US 2026/0136942 A1
(43) Pub. Date: May 14, 2026

(54) ADDITIVELY MANUFACTURED COAXIAL INTERCONNECTS

(71) Applicant: BAE Systems Information and Electronic Systems Integration Inc., Nashua, NH (US)

(72) Inventors: Caprice Gray Haley, Cambridge, MA (US); Yash Sahoo, Chelmsford, MA (US); Ian P. Armstrong, Concord, NH (US)

(21) Appl. No.: 18/947,704

(22) Filed: Nov. 14, 2024

(51) Int. Cl. H01L 23/66; H01P 3/08; H01P 5/08

(52) U.S. Cl. CPC H10W 44/20; H01P 3/08; H01P 5/085; H10W 44/216; H10W 44/234; H10W 44/251

(57) ABSTRACT

Coaxial interconnects formed by additive manufacturing. In one example, a method of electrically connecting an integrated circuit chip to an off-chip radio frequency (RF) waveguide includes providing an integration substrate having the integrated circuit chip and the RF waveguide mounted thereon, and printing, using an additive manufacturing apparatus, a coaxial interconnect extending between a plurality of first metal contact regions on the integrated circuit chip and a plurality of second metal contact regions on the RF waveguide, the coaxial interconnect including a metal core and a metal shield at least partially surrounding the metal core and arranged to be coaxial with the metal core.

### FIELD OF DISCLOSURE

The present disclosure relates to additive manufacturing and, more particularly, to systems and processes for producing coaxial interconnects using additive manufacturing.

### BACKGROUND

Monolithic microwave integrated circuits (MMICs) are used in various applications. In systems that incorporate MMICs, a MMIC is mounted on a substrate and interconnects such as wire bonds or ribbon bonds are used to connect the MMIC to other components on the same or different substrates. As operating signal frequencies increase, for example up to 40 Gigahertz (GHz) and higher, losses associated with the interconnects can significantly degrade system performance. Thus, a number of non-trivial issues remain with respect to producing high-frequency, high-performance systems incorporating MMICs or other integrated circuits.

### SUMMARY

Aspects and embodiments are directed to techniques for producing coaxial interconnects using additive manufacturing processes.

According to one example, an integrated system comprises an integration substrate, an integrated circuit mounted on the integration substate, a radio frequency (RF) waveguide on the integration substrate, and a coaxial interconnect electrically coupling the integrated circuit to the RF waveguide, the coaxial interconnect including a metal core and a metal shield at least partially surrounding the metal core along a length of the coaxial interconnect, wherein the coaxial interconnect includes a first portion coupled to the integrated circuit, a second portion coupled to the RF waveguide, and a transition portion extending between the first and second portions, the first portion having a first diameter, and the second portion having a second diameter different from the first diameter.

According to another example, an integrated system comprises an integration substrate, an integrated circuit mounted on the integration substate, the integrated circuit comprising a chip substrate, a conductor on a first surface of the chip substrate, one or more ground contact pads on the first surface of the chip substrate, a ground plane on a second surface of the chip substrate; and one or more metal-filled ground vias extending through the chip substrate to electrically connect the one or more ground contact pads to the ground plane, a radio frequency (RF) waveguide mounted on the integration substrate, and a coaxial interconnect electrically coupling the integrated circuit to the RF waveguide, the coaxial interconnect comprising a metal core coupled to the conductor and a metal shield at least partially surrounding the metal core and coupled to the one or more ground contact pads.

Another example is directed to a method of electrically connecting an integrated circuit chip to an off-chip radio frequency (RF) waveguide, the method comprising providing an integration substrate having the integrated circuit chip and the RF waveguide mounted thereon, and printing, using an additive manufacturing apparatus, a coaxial interconnect extending between a plurality of first metal contact regions on the integrated circuit chip and a plurality of second metal contact regions on the RF waveguide, the coaxial interconnect including a metal core and a metal shield at least partially surrounding the metal core and arranged to be coaxial with the metal core.

Still other aspects and advantages of these examples are described in detail below. Examples disclosed herein may be combined with other examples in any manner consistent with at least one of the principles disclosed herein, and references to “an example,” “some examples,” “various examples,” “one example” or the like are not necessarily mutually exclusive and are intended to indicate that a particular feature, structure, or characteristic described may be included in at least one example. The appearances of such terms herein are not necessarily all referring to the same example.

### BRIEF DESCRIPTION OF THE DRAWINGS

In the figures:

FIG. 1A is a diagram illustrating an example of a coaxial interconnect coupled to a coplanar waveguide, according to aspects of the present disclosure;

FIG. 1B is a diagram illustrating an example of a coaxial interconnect with a wire frame, according to aspects of the present disclosure;

FIG. 1C is a diagram illustrating an example of a coaxial interconnect with a slit frame, according to aspects of the present disclosure;

FIG. 2 is a side view of one example of an integrated system including a coaxial interconnect coupling together an integrated circuit chip and an RF waveguide, according to aspects of the present disclosure;

FIG. 3A is a partially transparent perspective view of an example of the integrated system of FIG. 2, according to aspects of the present disclosure;

FIG. 3B is a diagram illustrating some dimensions of an example of a portion of a coaxial interconnect, according to aspects of the present disclosure;

FIG. 4 is a perspective view of an example of a coaxial interconnect in a down-bond configuration, according to aspects of the present disclosure; and

FIG. 5 is a block diagram of one example of a computing system that can be used to produce coaxial interconnects using additive manufacturing techniques, according to aspects of the present disclosure.

Although the following detailed description will proceed with reference being made to illustrative embodiments, many alternatives, modifications, and variations thereof will be apparent in light of this disclosure.

### DETAILED DESCRIPTION

Techniques are disclosed herein for fabricating coaxial interconnects that can be used to couple an integrated circuit, such as a MMIC or other chip, to other “off-chip” components, such as a waveguide, for example. Using additive manufacturing processes, techniques disclosed herein may facilitate producing low-loss packaging solutions for high-power gallium nitride (GaN), gallium arsenide (GaAs) and/or other semiconductor-based MMICs. As described in more detail below, certain examples apply electrochemical additive manufacturing techniques to access geometries not accessible via standard manufacturing techniques and use these geometries to produce coaxial interconnects having various advantageous properties. For example, certain geometries can be configured to optimize impedance matching at both ends of the coaxial interconnect and to compensate for dielectric constant mismatches between the integration substrate and the chip, as described further below.

According to certain examples, a method of electrically connecting an integrated circuit chip to an off-chip radio frequency (RF) waveguide comprises providing an integration substrate having the integrated circuit chip and the RF waveguide mounted thereon, and printing, using an additive manufacturing apparatus, a coaxial interconnect extending between a plurality of first metal contact regions on the integrated circuit chip and a plurality of second metal contact regions on the RF waveguide, the coaxial interconnect including a metal core and a metal shield at least partially surrounding the metal core and arranged to be coaxial with the metal core.

In some examples, an integrated system comprises an integration substrate, the integrated circuit chip (e.g., a MMIC) mounted on the integration substrate, the RF waveguide on the integration substrate, and the coaxial interconnect electrically coupling the integrated circuit to the RF waveguide. As described above, the coaxial interconnect may include a metal core and a metal shield at least partially surrounding the metal core along a length of the coaxial interconnect. In some examples, the coaxial interconnect includes a first portion coupled to the integrated circuit, a second portion coupled to the RF waveguide, and a transition portion extending between the first and second portions, the first portion having a first diameter, and the second portion having a second diameter different from the first diameter. The diameters of the first and second portions can be selected to provide impedance matching at both ends of the coaxial interconnect.

These and other aspects of coaxial interconnect structures and processes for producing them are described in more detail below.

### General Overview

High-frequency MMICs can be used in a wide variety of applications. In some examples, these devices are configured to operate at high radio frequency (RF) power levels and at very high frequencies (e.g., millimeter-wave applications may involve signal frequencies above 30 GHZ). In some systems, a MMIC (or other chip) is mounted on a carrier substrate (also referred to herein as an integration substrate) and connected to other components via one or more waveguides on the carrier substrate. The MMIC can be coupled to the waveguide(s) by one or more conductive interconnects. In some instances, although the MMIC chip itself can be designed and configured to achieve very high performance (e.g., low loss, high frequency, high power operation, etc.) and a low-loss coaxial or coplanar waveguide can be used to maintain signal integrity on the carrier substrate itself, the interconnects between the two can introduce significant loss and/or other constraints into the overall system. For example, some integration approaches include using wire bonds or ribbon bonds to connect the MMIC or other chip to the waveguide on the carrier substrate, which can introduce significant loss due to the inductance loop associated with the wire/ribbon bond. One possible solution, particularly in high-frequency applications (e.g., signal frequencies at 40 GHz and higher), is to mount the MMIC in an “upside-down” or “flip-chip” configuration to reduce the length of the wire/ribbon bonds, which may reduce losses associated with wire/ribbon bond interconnects. While flip-chip mounting can facilitate improved signal integrity through the chip-to-substrate interconnects, it can create issues with respect to thermal management, which may be disadvantageous in some applications.

Accordingly, techniques are disclosed herein for providing micro coaxial interconnects that can be used to connect a MMIC or other chip to a waveguide on a carrier/integration substrate, for example. As described further below, in some examples, the coaxial interconnects can be formed using additive manufacturing techniques, such as electrochemical additive manufacturing. Thus, certain examples provide techniques by which coaxial interconnect structures can be produced for microelectronics packaging and/or other applications using a fully additive process. In comparison to wire/ribbon bonding techniques, additively manufactured coaxial interconnects according to examples described herein may provide higher frequency, lower loss, higher isolation, higher reliability, and lower cost IC interfaces. While these benefits may be applicable to all frequency domains, the coaxial interface technology described herein may provide particular advantages for millimeter wave (mm-wave) applications and signal frequencies above 30 GHz, where inductive losses associated with wire/ribbon bonds can be a significant limiting factor. Further, because examples of the coaxial interconnects described herein have lower loss, they can be made longer, thereby mitigating the need for flip-chip mounting. Integrating additively manufactured coaxial interconnects according to examples described herein may provide a cost-effective way to achieve MMIC-based systems having low-loss, high-power, mm-wave capabilities.

According to certain examples, coaxial interconnects are produced by applying three-dimensional (3D) metal printing techniques, such as electrochemical additive manufacturing, aerosol jet printing, or laser-induced molten metal printing, for example. In some examples, the coaxial interconnect can be made using the same metal (e.g., gold, copper, platinum, silver, etc.) as is used in the microfabrication of the chip, thereby reducing conductive losses that can arise from metal mismatches. As described further below, additively manufactured coaxial interconnects according to certain examples can be configured with geometries that allow for optimized impedance matching at both the on-chip end and off-chip end, thereby providing a mechanism by which to compensate for dielectric mismatches between the integration substrate and the chip. In addition, the coaxial shield may provide low-inductance RF isolation and can inhibit crosstalk with signals carried by other nearby conductors.

In addition, certain examples provide modified on-chip ground contacts to further minimize inductance due to on-chip grounding. As described further below, in some examples, these modified ground contacts include metal-filled grounding vias. Used in combination with the coaxial interconnects described herein, these filled grounding vias can facilitate extending the RF cutoff frequency into the W-band (e.g., 75-110 GHZ) and higher.

### Example Coaxial Interconnect Structures

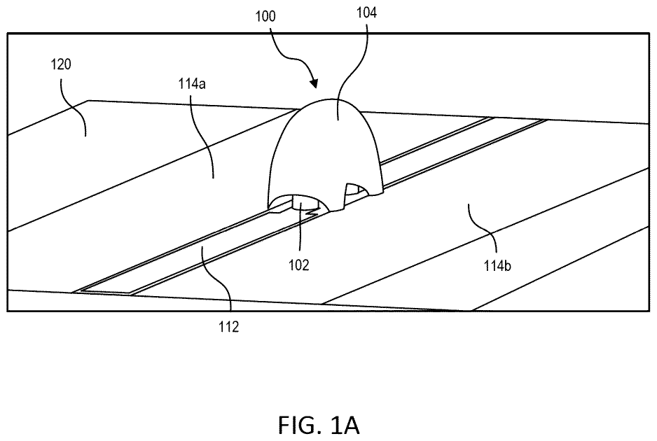

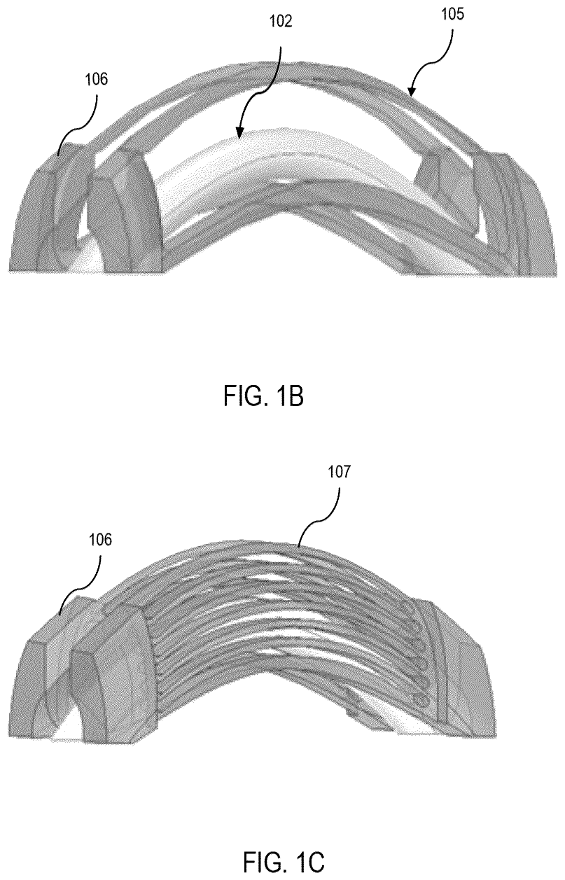

Referring to FIG. 1A, illustrated is a diagram of an example of a coaxial interconnect 100 coupling together two sections of a coplanar waveguide 110. The coplanar waveguide 110 is formed on a substrate 120 and includes a central signal-carrying conductor 112 with two ground-carrying conductors 114a, 114b disposed on either side of the central conductor 112. The coaxial interconnect 100 includes a central conductive core 102 and an outer shield or ground conductor 104 that at least partially surrounds the core 102 and is arranged to be coaxial with the core 102. Both the core 102 and the shield 104 are metal structures. The core 102 is coupled to the central conductor 112 of the waveguide 110, and the shield 104 is coupled to the ground-carrying conductors 114a, 114b of the waveguide 110.

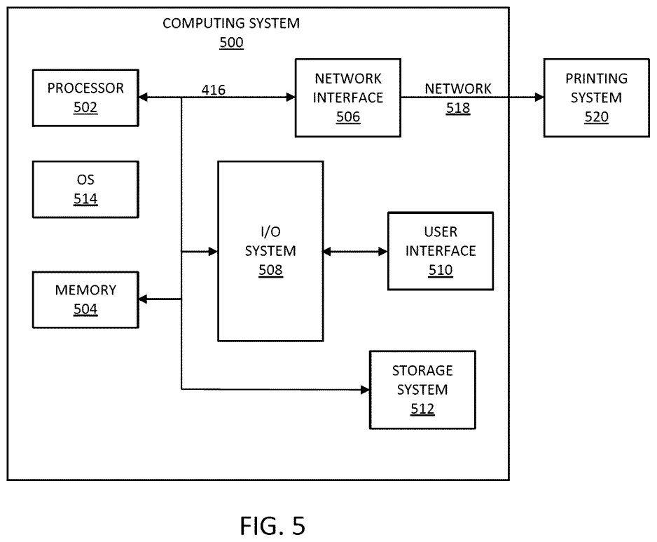

According to certain examples, the coaxial interconnect 100 can be produced using an additive manufacturing, or 3D printing, system and process. In particular, the core 102 and the shield 104 can be deposited onto conductive print surfaces (e.g., metal contact pads) using a printing system (e.g., the printing system 520 illustrated in FIG. 5) that includes a 3D printer or other additive manufacturing apparatus capable of depositing/printing metals in 3D space. In some examples, the printing system 520 may be operated under the control of a computing system such as the computing system 500 described below with reference to FIG. 5. The computing system 500 may include a user interface 510 to allow a user to program or control one or more operating parameters of the printing system 520, as described further below.

In some examples, the printing system 520 includes a 3D printer, such as an aerosol jet printer, that can be configured to print metal structures using one or more types of conductive inks (e.g., copper inks, gold inks, etc.). In other examples, the printing system 520 includes a laser-driven printing apparatus that uses a pulsed laser as an energy source for liquid metal printing. In further examples, the printing system 520 includes an electrochemical additive manufacturing tool capable of electroplating metals in 3D space. One example of an electrochemical printing system is the CERES printing system available from Exaddon AG based in Switzerland.

An electrochemical printing system, such as the CERES tool, for example, may include a small printing nozzle that is immersed in an electrolyte bath. Precisely regulated air pressure can be used to push a liquid containing metal ions through a microchannel inside the printing nozzle. In some examples, the liquid flow is very small, for example, on the order of femtoliters per second. At the tip of the printing nozzle, the liquid is released onto the conductive print surface, and the dissolved metal ions are electrodeposited into solid metal atoms. These metal atoms grow together into small building blocks referred to as “voxels.” To form the coaxial interconnect 100, the core 102 and the shield 104 may be produced by the printing system 520, voxel by voxel, according to a selected geometry. In some examples, the selected geometry can be programmed into the computing system 500 (e.g., via the user interface 510 or accessed from storage system 512) and the computing system 500 controls the printing system 520 to move the printing nozzle in 3D space so as to print the coaxial interconnect 100 according to the selected geometry. In some examples, the printing system 520 can include a feedback system, such as a camera or other optical sensor, that allows the printing system 520 and/or computing system 500 to monitor the deposition of each voxel (or other print unit in the case of other printing tools) until the complete structure has been produced.

Thus, by specifying a particular geometry, and causing the computing system 500 to appropriately control the printing system 520 according to the specified geometry, the coaxial interconnect 100 can be produced having selected dimensions and shape. For example, characteristics of the coaxial interconnect that can be specified may include the length of the coaxial interconnect, the height of the structure above the substrate 120 over the length of the interconnect, the inner and outer diameters of the core 102, the inner and outer diameters of the shield 104, and/or the spacing between the core 102 and the shield 104. In some examples, additive manufacturing techniques can be used to print pure metal structures that form the core 102 and shield 104 of the coaxial interconnect 100, with air providing the separating dielectric between the outer surface of the core 102 and the inner surface of the shield 104. Furthermore, any of a variety of metals can be used to produce the core 102 and shield 104 of the coaxial interconnect 100, including gold, copper, platinum, silver, or nickel, for example. Thus, additive manufacturing techniques allow for a high degree of flexibility in producing examples of the coaxial interconnect 100 such that the geometry of any particular coaxial interconnect can be adapted for a particular application and/or placement within an integrated system.

Simulations of an example of the coaxial interconnect 100 (in the configuration shown in FIG. 1A, coupled to the coplanar waveguide 110 formed on a 4-mil Rogers laminate substrate) have demonstrated that the coaxial interconnect can achieve significantly improved performance versus a standard ribbon bond in the same application. For example, simulations have shown that an example of the coaxial interconnect 100 having a length of 1.2 millimeters (mm) has improved return loss, compared to a ribbon bond having a length of only 0.2 mm, over a frequency range from 10 GHz to more than 100 GHz. Simulations have further demonstrated that the 1.2 mm coaxial interconnect has similar insertion loss as does the 0.2 mm ribbon bond for frequencies up to about 75 GHz, and significantly reduced insertion loss (relative to the 0.2 mm ribbon bond) above 75 GHz. Thus, as described above, examples of the coaxial interconnect can offer significantly reduced loss relative to wire/ribbon bonds for the same or similar connection scenarios (e.g., connecting the same two portions of the central signal-carrying conductor 112 of the coplanar waveguide 110). In some examples, the coaxial interconnect 100 can be configured to exhibit a maximum insertion loss of 2.5 dB at operational frequencies of the systems/devices in which it is used. In some examples, the operational frequency may above 10 GHZ, above 30 GHZ, or higher. Furthermore, because the improved performance (e.g., low insertion loss and/or return loss) can be achieved with a far longer coaxial interconnect (e.g., as described above, a 1.2 mm length coaxial interconnect offers reduced loss relative to a far shorter 0.2 mm ribbon bond), coaxial interconnects offer greater flexibility in forming connections between structures/devices, which can be advantageous in many applications, as described further below. In addition, the ability to use longer chip-to-substrate interconnects reduces the need for flip-chip mounting of MMICs or other integrated circuits, thereby simplifying thermal management in high-power applications.

Referring to FIG. 1B, the central conductive core 102 employs a pseudo-coaxial wire frame geometry shield 105 that uses less material and is faster to print than a solid shield. The wire frame shield 105 in this example has an open collar 106 that allows the shield 105 to be installed or replaced to an existing central conductive core 102. The bulk collar 106 may modified to transition from the dimensions of an input or output waveguide to the coaxial dimensions, referencing the coaxial inner and outer diameters. The wire frame shield 105 in this example reduces print volume by about 71% as compared to a full shield. The partially cylindrical models also provides for impedance chip-to-substrate matching. Simulations for the average RF (return loss) for the wire frame design shows similar performance to conventional ribbon bonds through 60 GHz with S11 staying below −15 dB. Above 60 GHz, return loss is 10 dB to 30 dB lower than ribbon bonds through 155 GHz. In comparison to an identical full-shield coaxial model, the RMS of the return loss (S11) through 155 GHz was reduced by 5%. Despite the decrease in performance for the wire frame design, the average return loss is well below −10 dB as recommended for high-frequency GaN modules. The performance trade-off with consideration of the print volume makes the wire-frame geometry well suited for AM micro-coax, exceeding performance well over 100 GHz.

In FIG. 1C, a pseudo-coaxial slit frame shield 107 is used for the central conductive core 102. The slit frame shield 107 also uses less material and is faster to print than a solid shield. The RMS return loss through 155 GHz for slit frame shield 107 improved by 10% in comparison to the full-shield interconnect. Up to 70 GHz, the return loss is 5 dB to 45 dB lower than that of a full-shield coaxial model.

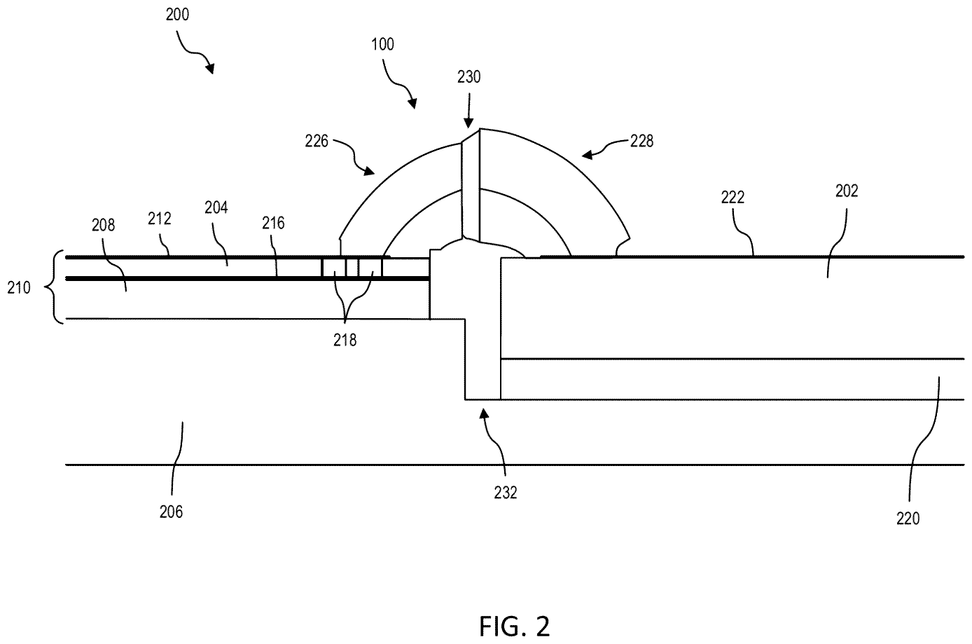

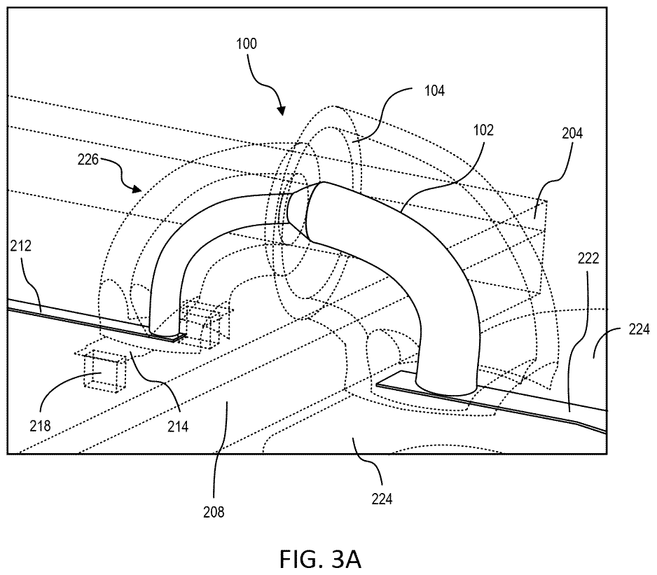

Turning now to FIG. 2, there is illustrated a side view of one example of an integrated system 200 including an example of the coaxial interconnect 100 configured to connect a MMIC 210 to a waveguide on a waveguide substrate 202. In this example, the MMIC 210 includes a chip substrate 204 made of a semiconductor material, such as a gallium nitride (GaN) or gallium arsenide (GaAs), for example, that is mounted to an integration substrate 206 via an epoxy layer 208. The waveguide substrate 202 may be similarly mounted to the integration substrate 206 via an epoxy layer 220. In some examples, the epoxy layers 208 and 220 are made of silver epoxy; however, in other examples, other materials can be used. In some examples, the waveguide substrate 202 is made of Alumina; however, in other examples, other materials can be used.

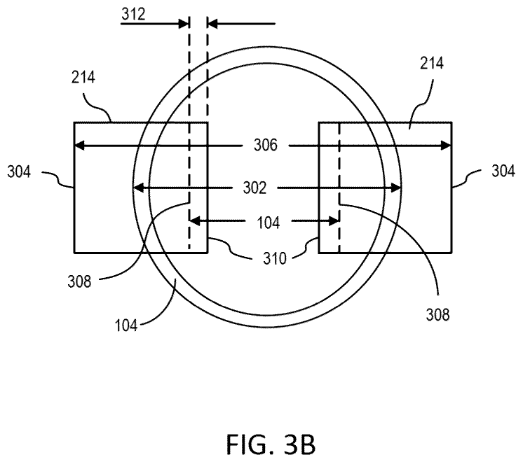

FIG. 3A illustrates a corresponding partially transparent perspective view of an example of the integrated system of FIG. 2. Referring to FIGS. 2 and 3A, the MMIC 210 includes a signal conductor 212 that is coupled to the core 102 of the coaxial interconnect 100, and a ground contact pads 214 that are coupled to the shield 104 of the coaxial interconnect 100. Although a full shield 104 is illustrated in FIGS. 2 and 3A, it will be appreciated that in other examples, the full shield 104 may be replaced with a wire frame shield 105 or a pseudo-coaxial slit frame shield 107, as described above. Accordingly, while the following discussion refers to the shield 104, it will be appreciated that the various aspects, attributes, and/or configurations may be applied in examples using a wire frame shield 105 or a pseudo-coaxial slit frame shield 107. The ground contact pads 214 are coupled to a ground conductor, or ground plane 216, through filled ground vias 218, as described further below. On the substrate 202, the core 102 of the coaxial interconnect 100 is coupled to a central conductor 222 of the waveguide, and the shield 104 of the coaxial interconnect 100 is coupled to ground conductors 224 (e.g., similar to the arrangement shown in FIG. 1). In some examples, the metal filling the ground vias 218 is the same metal used for the ground contact pads 214 and ground plane 216 and for the signal conductor 212. The metal may be any conductive metal, including, for example, gold, silver, copper, nickel, aluminum, or platinum. As described above, to minimize conduction losses, the same metal can also be used for the core 102 and shield 104 of the coaxial interconnect 100.

Referring to FIG. 3B, in some examples, the coaxial interconnect 100 is configured with a maximum outer diameter 302 of the shield 104 (or the shield 105 or 107 in other examples) being approximately equal to a width of the launch contact to which the shield 104 is coupled. For example, the outer diameter 302 of the shield 104 may extend to/from the outer edges 304 of the contact pads 214 on either side of the coaxial interconnect 100. Thus, a maximum value of the outer diameter 302 of the shield is represented in FIG. 3B by dimension 306. In some examples, a minimum outer diameter 302 of the shield 104 may extend to/from specified points 308 measured from the inner edges 310 of the contact pads 214 on either side of the coaxial interconnect 100. In one example, the specified points 308 individually are spaced a distance 312 inside the inner edge 308 of the respective contact pad 214, as shown in FIG. 3B. In some examples, the distance 312 is the larger of (i) twice the minimum voxel size of the printing system 520 used to produce the coaxial interconnect 100, (ii) or twice the skin depth of the metal of the shield 104 at the operational frequency of the device in which the coaxial interconnect 100 is to be used.

Returning to the example illustrated in FIGS. 2 and 3A, in some instances the coaxial interconnect 100 comprises three regions, namely a “chip-side” first portion 226, an “off-chip-side” second portion 228, and a transition portion 230 between the first portion 226 and the second portion 228. As described above, forming the coaxial interconnect 100 using additive manufacturing techniques allows significant control over, and flexibility in, the geometry of coaxial interconnect. For example, the diameter of the coaxial interconnect 100, e.g., the diameters of the core 102 and shield 104, can be varied arbitrarily over the length of the coaxial interconnect 100. This allows the geometry of the coaxial interconnect 100 to be controlled to achieve impedance matching at either or both ends of the coaxial interconnect. For example, as shown in FIGS. 2 and 3A, the core 102 and the shield 104 can have first respective diameters in the first portion 226 and second respective diameters in the second portion 228. As a result, the coaxial interconnect 100 may present a first impedance at a coupling end of the first portion 226 where the coaxial interconnect 100 is coupled to the MMIC 210, and a second impedance at a coupling end of the second portion 228 where the coaxial interconnect 100 is coupled to the waveguide on the waveguide substrate 202. In the illustrated example, the diameters of the core 102 and the shield 104 are smaller in the first portion 226 than in the second portion 228; however, the opposite configuration can be used in other examples.

According to certain examples, the diameters of the core 102 and the shield 104 in the first portion 226 can be selected to impedance match the coaxial interconnect 100 to the structure on the MMIC 210 to which the coaxial interconnect is coupled at the coupling end of the first portion 226. Similarly, the diameters of the core 102 and the shield 104 in the second portion 228 can be selected to impedance match the coaxial interconnect 100 to the waveguide on the waveguide substrate 202 to which the coaxial interconnect is coupled at the coupling end of the second portion 228. The diameters of the core 102 and the shield 104 in the first and second portions 226, 228 can be independently selected. Thus, good impedance matching may be achieved at both ends of the coaxial interconnect 100, which can compensate for dielectric constant mismatches between the substrate 202 and the MMIC 210, for example. This, in turn, may significantly reduce return loss and/or insertion loss associated with the coaxial interconnect, as described above. In addition, by providing good impedance matching at both ends of the coaxial interconnect 100, the cut-off frequency of the coaxial interconnect can be extended into very high frequency ranges, for example, above 75 GHZ.

According to certain examples, the diameters of the core 102 and the shield 104 can be tapered over the transition portion 230 to smoothly transition the impedance of the coaxial interconnect between the first impedance presented at the coupling end of the first portion 226 and the second impedance presented at the coupling end of the second portion 228. In some examples, the taper in the sizes of the diameters of the core 102 and the shield 104 can be essentially uniform (e.g., to the voxel level) over the length of the transition portion 230. By tapering the diameters of the core 102 and the shield 104 over the transition portion 230, a step-change in the diameter sizes, and therefore in the impedance, which may otherwise result in potentially significant reflections and therefore return loss, can be avoided.

As illustrated in FIGS. 2 and 3A, in some examples, ground contacts for the coaxial interconnect 100 on the MMIC 210 include the filled ground vias 218. Thus, as described above, on the MMIC 210, the shield 104 of the coaxial interconnect 100 is coupled to one or more ground contacts 214 on a surface of the MMIC substrate 204. These ground contact pads 214 are coupled though respective filled ground vias 218, to the ground conductor/ground plane 216. For wire/ribbon bond interconnects, filled vias, which form a shunt path to the ground plane 216, may cause poor performance due to higher reflection loss. In contrast however, it has been found that the filled ground vias 218 may be beneficial for coaxial grounding. For coaxial interconnects, the filled ground vias 218 may serve to minimize inductance associated with on-chip grounding through the ground plane 216. Without the filled ground vias 218, an inductance loop can be formed through the MMIC substrate 204 between the ground contact pads 214 and the ground plane 216. The use of the filled ground vias 218 helps to mitigate this inductance loop to reduce loss and extend the cutoff frequency of the coaxial interconnect, for example, into the W band (˜75 GHz-110 GHZ) and higher.

As described above, when wire or ribbon bonds are used to electrically connect a MMIC or other chip to an off-chip waveguide, the relatively high losses associated with these bonds drive a need to make the bonds as short as possible. Accordingly, as shown in FIG. 2, for example, in some integrated systems, reduced height regions, or valleys 232, may be formed in the integration substrate 206 to accommodate the waveguide substrate 202 such that upper surfaces of the substrate 202 and the MMIC 210 can be relatively level with one another or approximately in the same plane (e.g., within a few micrometers or less). This allows the length of the connecting structure (e.g., the coaxial interconnect 100 in the example shown in FIG. 2) to be shorter. For example, the connecting structure need only span the horizontal distance between the two devices being coupled together, rather than also having to span some vertical offset as well. In the example shown in FIG. 2, the waveguide substrate 202 is shown positioned in the valley region 232; however, it will be appreciated that the same result (minimizing vertical offset between upper surfaces of the substrate 202 and the MMIC 210) can be achieved by building up a region of the integration substrate 206 where the MMIC 210 is mounted (e.g., producing a mesa instead of a valley).

As also described above, examples of the coaxial interconnect 100 can be constructed to have significantly reduced loss relative to a wire bond or ribbon bond of the same length. As a result, the coaxial interconnect can be made much longer, while still providing good performance even for high-frequency applications (e.g., in the 30 GHZ-110 GHz range). For example, the coaxial interconnect 100 may have a length that may be several millimeters or more, while still exhibiting acceptable/tolerable loss (e.g., less than 2.5 dB). Accordingly, in some applications and examples, coaxial interconnects 100 can be made long enough to accommodate some vertical offset between the MMIC 210 and an off-chip structure, thereby avoiding the need to produce raised/lowered regions on the integration substate 206.

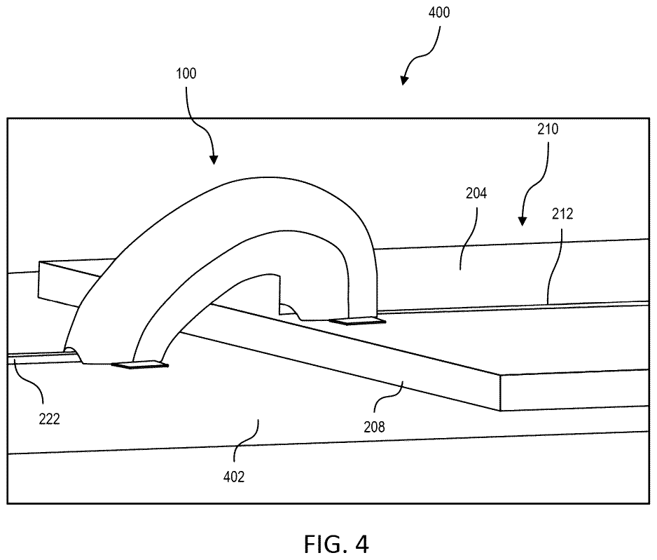

Referring to FIG. 4, there is illustrated an example of integrated system 400 in which the coaxial interconnect 100 is configured in a “down-bond” arrangement. In this example, the MMIC 210 is mounted on an integration substrate 402 that also has the conductor 222 formed thereon (note that for simplicity, the ground conductor(s) 214 and contact pad(s) 224 are not illustrated). The coaxial interconnect 100 is formed to accommodate the vertical offset (e.g., the height of the MMIC 210) between the on-chip conductor 212 and the off-chip conductor 222, as well as the horizontal distance between the coupling points at the two conductors. Although not shown in FIG. 4, it will be appreciated that in some examples, a down-bond coaxial interconnect 100 may include the impedance matching geometry (e.g., regions with differently sized core/shield diameters and a tapered transition region) described above with reference to FIGS. 2, 3A, and 3B.

Thus, examples provide coaxial interconnects that are additively manufactured and can be used to electrically coupled a MMIC or other chip to an off-chip waveguide (or other conductor). In examples, the coaxial configuration maintains a small form factor while offering improved RF performance relative to other bonding arrangements, such as wire bonds or ribbon bonds, for example. As described above, through the use of metal-printing additive manufacturing techniques, such as electrochemical additive manufacturing (e.g., using electrophoretic deposition of metal particles), pure metal structures forming the core 102 and shield 104 (or shields 105 or 107) of the coaxial interconnect can be produced. In some examples, conductive losses may be minimized by leveraging electrochemical additive manufacturing to print the same metal for the coaxial interconnect 100 as is used in microfabrication the MMIC 210 (e.g., gold or other conductive metals). Furthermore, using additive manufacturing provides high flexible control over the geometry of the coaxial interconnect, and allows impedance matching configurations to be built into the structure. For example, as described above, the diameters of the core 102 and shield 104, 105, or 107 can be adjusted along the length of the coaxial interconnect 100 to compensate for differences in dielectric constant between the MMIC substrate 204 and the waveguide substrate 202. In addition, a ground contact geometry that minimizes inductance can be provided, allowing high cutoff frequency (e.g., well into the W band and beyond).

According to examples and techniques disclosed herein, an integrated system can be produced in which a coaxial interconnect 100 is connected at one end to a MMIC 210 with GaN, GaAs or other wide-bandgap semiconductor epitaxy, and at the other end to an RF waveguide on a waveguide substrate 202. In some examples, the MMIC 210 includes filled ground vias 218 adjacent to the on-chip conductor(s) coupled to the coaxial interconnect 100, as described above, to minimize ground loop inductance and maximize cutoff frequency. In some examples, an integration substrate 206, that may be of a different material than the waveguide substrate 202, is used as a carrier for the waveguide substrate 202 and the MMIC 210, as shown in FIG. 2, for example. In other examples, the RF waveguide can be patterned directly onto the integration substrate 402 to which the MMIC 210 is mounted, as shown in FIG. 4, for example. As described above, the integration substrate can be planar, such that the coaxial interconnect has a down-bond geometry, as illustrated in FIG. 4, or can be machined or otherwise patterned to reduce vertical offset between the on-chip and off-chip bonding points, as illustrated in FIG. 2, for example.

Examples of the additively manufactured coaxial interconnects described herein may thus provide a high-performance bonding solution that can be adapted to a wide variety of different structures, system configurations, and/or applications.

### Example Computing System

FIG. 5 illustrates an example computing system 500 that can be used to control the printing system 520 to produce coaxial interconnects as described above. In some embodiments, the computing system 500 may host, or otherwise be incorporated into a personal computer, workstation, server system, laptop computer, ultra-laptop computer, tablet, touchpad, portable computer, handheld computer, palmtop computer, personal digital assistant (PDA), cellular telephone, combination cellular telephone and PDA, smart device (for example, smartphone or smart tablet), mobile internet device (MID), messaging device, data communication device, embedded system, and so forth. Any combination of different devices may be used in certain embodiments. In some embodiments, the computing system 500 represents one system in a network of systems coupled together via controlled area network (CAN) bus or other network bus.

In some examples, the computing system 500 may comprise any combination of a processor 502, a memory 504, a network interface 506, an input/output (I/O) system 508, a user interface 510, and a storage system 512. As shown in FIG. 5, a bus and/or interconnect 516 is also provided to allow for communication between the various components listed above and/or other components not shown. The computing system 500 can be coupled to a network 518 through the network interface 506 to allow for communications with other computing devices, platforms, or resources, including, for example, the printing system 520. Other componentry and functionality not reflected in the block diagram of FIG. 5 will be apparent in light of this disclosure, and it will be appreciated that other embodiments are not limited to any particular hardware configuration.

The processor 502 can be any suitable processor and may include one or more coprocessors or controllers to assist in control and processing operations associated with the computing system 500. In some embodiments, the processor 502 may be implemented as any number of processor cores. The processor (or processor cores) may be any type of processor, such as, for example, a micro-processor, an embedded processor, a digital signal processor (DSP), a graphics processor (GPU), a network processor, a field programmable gate array or other device configured to execute code. The processors may be multithreaded cores in that they may include more than one hardware thread context (or “logical processor”) per core.

The memory 504 can be implemented using any suitable type of digital storage including, for example, flash memory and/or random access memory (RAM). In some embodiments, the memory 504 may include various layers of memory hierarchy and/or memory caches as are known to those of skill in the art. The memory 504 may be implemented as a volatile memory device such as, but not limited to, a RAM, dynamic RAM (DRAM), or static RAM (SRAM) device. The storage system 512 may be implemented as a non-volatile storage device such as, but not limited to, one or more of a hard disk drive (HDD), a solid-state drive (SSD), a universal serial bus (USB) drive, an optical disk drive, tape drive, an internal storage device, an attached storage device, flash memory, battery backed-up synchronous DRAM (SDRAM), and/or a network accessible storage device. In some embodiments, the storage system 512 may comprise technology to increase the storage performance enhanced protection for valuable digital media when multiple hard drives are included. In some examples, configuration files specifying the geometries of one or more types of coaxial interconnects 100 can be stored in the storage system 512 for access by the processor 502 to control the printing system 520 to produce the coaxial interconnect(s) 100.

The processor 502 may be configured to execute an Operating System (OS) 514 which may comprise any suitable operating system, such as Google Android (Google Inc., Mountain View, CA), Microsoft Windows (Microsoft Corp., Redmond, WA), Apple OS X (Apple Inc., Cupertino, CA), Linux, or a real-time operating system (RTOS). As will be appreciated in light of this disclosure, the techniques provided herein can be implemented without regard to the particular operating system provided in conjunction with the computing system 500, and therefore may also be implemented using any suitable existing or subsequently-developed platform.

The network interface 506 can be any appropriate network chip or chipset which allows for wired and/or wireless connection between other components of the computing system 500 and/or the network 518, thereby enabling the computing system 500 to communicate with other local and/or remote computing systems, servers, cloud-based servers, and/or other resources. Wired communication may conform to existing (or yet to be developed) standards, such as, for example, Ethernet. Wireless communication may conform to existing (or yet to be developed) standards, such as, for example, cellular communications including LTE (Long Term Evolution), Wireless Fidelity (Wi-Fi), Bluetooth, and/or Near Field Communication (NFC). Exemplary wireless networks include, but are not limited to, wireless local area networks, wireless personal area networks, wireless metropolitan area networks, cellular networks, and satellite networks.

The I/O system 508 may be configured to interface between various I/O devices and other components of the computing system 500. I/O devices may include, but not be limited to, a user interface 510. The user interface 510 may include devices (not shown) such as a display element, touchpad, keyboard, mouse, and/or speaker, to allow a user to interact with the computing system 500. For example, the user interface 510 may allow a user to control one or more operating parameters of the printing system 520.

It will be appreciated that in some embodiments, the various components of the computing system 500 may be combined or integrated in a system-on-a-chip (SoC) architecture. In some embodiments, the components may be hardware components, firmware components, software components or any suitable combination of hardware, firmware or software.

In various embodiments, the computing system 500 may be implemented as a wireless system, a wired system, or a combination of both. When implemented as a wireless system, the computing system 500 may include components and interfaces suitable for communicating over a wireless shared media, such as one or more antennae, transmitters, receivers, transceivers, amplifiers, filters, control logic, and so forth. An example of wireless shared media may include portions of a wireless spectrum, such as the radio frequency spectrum and so forth. When implemented as a wired system, the computing system 500 may include components and interfaces suitable for communicating over wired communications media, such as input/output adapters, physical connectors to connect the input/output adaptor with a corresponding wired communications medium, a network interface card (NIC), disc controller, video controller, audio controller, and so forth. Examples of wired communications media may include a wire, cable metal leads, printed circuit board (PCB), backplane, switch fabric, semiconductor material, twisted pair wire, coaxial cable, fiber optics, and so forth.

Unless specifically stated otherwise, it may be appreciated that terms such as “processing,” “computing,” “calculating,” “determining,” or the like refer to the action and/or process of a computer or computing system, or similar electronic computing device, that manipulates and/or transforms data represented as physical quantities (for example, electronic) within the registers and/or memory units of the computer system into other data similarly represented as physical quantities within the registers, memory units, or other such information storage transmission or displays of the computer system. The embodiments are not limited in this context.

The terms “circuit” or “circuitry,” as used in any embodiment herein, may comprise, for example, singly or in any combination, hardwired circuitry, programmable circuitry such as computer processors comprising one or more individual instruction processing cores, state machine circuitry, and/or firmware that stores instructions executed by programmable circuitry. The circuitry may include a processor and/or controller configured to execute one or more instructions to perform one or more operations described herein. The instructions may be embodied as, for example, an application, software, and/or firmware, configured to cause the circuitry to perform any of the aforementioned operations. Software may be embodied as a software package, code, instructions, instruction sets and/or data recorded on a computer-readable storage device. Software may be embodied or implemented to include any number of processes, and processes, in turn, may be embodied or implemented to include any number of threads in a hierarchical fashion. Firmware may be embodied as code, instructions or instruction sets and/or data that are hard-coded (e.g., nonvolatile) in memory devices. The circuitry may, collectively or individually, be embodied as circuitry that forms part of a larger system, for example, an integrated circuit (IC), an application-specific integrated circuit (ASIC), a system on-chip (SoC), desktop computers, laptop computers, tablet computers, servers, and/or smart phones. Other embodiments may be implemented as software executed by a programmable control device. As described herein, various embodiments may be implemented using hardware elements, software elements, or any combination thereof. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth.

Various embodiments may be implemented using hardware elements, software elements, or a combination of both. Examples of hardware elements may include processors, microprocessors, circuits, circuit elements (for example, transistors, resistors, capacitors, inductors, and so forth), integrated circuits, ASICs, programmable logic devices, digital signal processors, FPGAs, GPUs, logic gates, registers, semiconductor devices, chips, microchips, chipsets, and so forth. Examples of software may include software components, programs, applications, computer programs, application programs, system programs, machine programs, operating system software, middleware, firmware, software modules, routines, subroutines, functions, methods, procedures, software interfaces, application program interfaces, instruction sets, computing code, computer code, code segments, computer code segments, words, values, symbols, or any combination thereof. Determining whether an embodiment is implemented using hardware elements and/or software elements may vary in accordance with any number of factors, such as desired computational rate, power level, heat tolerances, processing cycle budget, input data rates, output data rates, memory resources, data bus speeds, and other design or performance constraints.

### Further Examples

The following examples pertain to further embodiments, from which numerous permutations and configurations will be apparent.

Example 1 is a 3D-printed metal interconnect having a coaxial geometry and which can be used to electrically connect a first structure on an integrated circuit (an on-chip structure) to a second structure on a substrate (an off-chip structure).

Example 2 includes the coaxial metal interconnect of Example 1, wherein the coaxial metal interconnect has a length exceeding one millimeter and a maximum insertion loss of 2.5 dB at frequencies in a range of 10 GHz to 110 GHz.

Example 3 includes the coaxial metal interconnect of one of Examples 1 or 2, wherein the coaxial metal interconnect is made of any one of gold, copper, silver, aluminum, platinum, or nickel.

Example 4 includes the coaxial metal interconnect of any one of Examples 1-3, wherein the coaxial metal interconnect includes a metal core, a metal shield at least partially surrounding the metal core, and an air dielectric between the metal core and the metal shield. The metal shield may be a full shield, a wire frame shield, or a slit frame shield.

Example 5 is a method of forming a metal coaxial interconnect using additive manufacturing.

Example 6 is an integrated system comprising an integration substrate, an integrated circuit mounted on the integration substate, a radio frequency (RF) waveguide on the integration substrate, and a coaxial interconnect electrically coupling the integrated circuit to the RF waveguide.

Example 7 includes the integrated system of Example 6, wherein the RF waveguide is on a waveguide substrate that is mounted to the integration substrate.

Example 8 includes the system of one of Examples 6 or 7, wherein the waveguide substrate comprise alumina.

Example 9 includes the system of any one of Examples 6-8, wherein the integrated circuit comprises a GaN or GaAs chip substrate.

Example 10 includes the integrated system of any one of Examples 6-9, wherein the coaxial interconnect is producing using a 3D metal printing process.

Example 11 includes the integrated system of Example 10, wherein the coaxial interconnect is made of any one of gold, copper, silver, aluminum, platinum, or nickel.

Example 12 includes the integrated system of any one of Examples 6-11, wherein the coaxial interconnect has a geometry configured to provide impedance matching between connections to the integrated circuit and to the RF waveguide.

Example 13 is a method of electrically connecting an integrated circuit chip to an off-chip radio frequency (RF) waveguide, the method comprising providing an integration substrate having the integrated circuit chip and the RF waveguide mounted thereon, and printing, using an additive manufacturing apparatus, first and second metal structures arranged to form a coaxial interconnect extending between a plurality of first metal contact regions on the integrated circuit chip and a plurality of second metal contact regions on the RF waveguide.

Example 14 is an integrated system comprising: an integration substrate; an integrated circuit on the integration substate; a radio frequency (RF) waveguide on the integration substrate; and a coaxial interconnect electrically coupling the integrated circuit to the RF waveguide, the coaxial interconnect including a metal core and a metal shield at least partially surrounding the metal core along a length of the coaxial interconnect, wherein the coaxial interconnect includes a first portion coupled to the integrated circuit, a second portion coupled to the RF waveguide, and a transition portion extending between the first and second portions, the first portion having a first diameter, and the second portion having a second diameter different from the first diameter.

Example 15 includes the integrated system of Example 14, wherein the coaxial interconnect has a maximum insertion loss of 2.5 dB at an operational frequency of the integrated system.

Example 16 includes the integrated system of one of Examples 14 or 15, wherein the metal core and the metal shield are made of gold.

Example 17 includes the integrated system of one of Examples 14 or 15, wherein the metal core and the metal shield are made of any one of copper, silver, nickel, platinum, or aluminum.

Example 18 includes the integrated system of any one of Examples 14-17, wherein the integrated circuit comprises a chip substrate, a conductor on a surface of the chip substrate, and one or more ground contact pads on the surface of the chip substrate, wherein the metal core of the coaxial interconnect is coupled to the conductor, and wherein the metal shield of the coaxial interconnect is coupled to the one or more ground contact pads.

Example 19 includes the integrated system of Example 18, wherein the one or more ground contact pads include a first and second ground contact pads positioned on either side of the coaxial interconnect, and wherein the metal shield of the coaxial interconnect has a maximum outer diameter equal to a distance between outer edges of the first and second ground contact pads.

Example 20 includes the integrated system of one of Examples 18 or 19, wherein the surface of the chip substrate is a first surface, and wherein integrated circuit further comprises: a ground plane on a second surface of the chip substrate; and one or more metal-filled ground vias extending through the chip substrate to electrically connect the one or more ground contact pads to the ground plane.

Example 21 includes the integrated system of any one of Examples 18-20, wherein the RF waveguide is patterned on the integration substrate, and wherein the first diameter of the first portion of the coaxial interconnect and the second diameter of the second portion of the coaxial interconnect are selected to compensate for a mismatch in dielectric constant between the integration substrate and the chip substrate.

Example 22 includes the integrated system of any one of Examples 18-20, wherein the RF waveguide is patterned on a waveguide substrate, wherein the waveguide substrate is mounted to the integration substrate, and wherein the first diameter of the first portion of the coaxial interconnect and the second diameter of the second portion of the coaxial interconnect are selected to compensate for a mismatch in dielectric constant between the waveguide substrate and the chip substrate.

Example 23 includes the integrated system of Example 22, wherein the waveguide substrate comprises alumina, and the chip substrate comprises gallium and nitrogen.

Example 24 includes the integrated system of any one of Examples 14-23, wherein the transition portion is tapered in diameter between the first diameter at a junction of the transition portion and the first portion and the second diameter at a junction of the transition portion and the second portion.

Example 25 includes the integrated system of any one of Examples 14-24, wherein the coaxial interconnect has a cutoff frequency above 75 gigahertz, for example, in a range of 75 gigahertz to 110 gigahertz.

Example 26 includes the integrated system of any one of Examples 14-25, wherein the metal shield is a full shield, wire frame shield or slit frame shield.

Example 27 is an integrated system comprising: an integration substrate; an integrated circuit mounted on the integration substate, the integrated circuit comprising a chip substrate, a conductor on a first surface of the chip substrate, one or more ground contact pads on the first surface of the chip substrate, a ground plane on a second surface of the chip substrate; and one or more metal-filled ground vias extending through the chip substrate to electrically connect the one or more ground contact pads to the ground plane; a radio frequency (RF) waveguide mounted on the integration substrate; and a coaxial interconnect electrically coupling the integrated circuit to the RF waveguide, the coaxial interconnect comprising a metal core coupled to the conductor and a metal shield at least partially surrounding the metal core and coupled to the one or more ground contact pads.

Example 28 includes the integrated system of Example 27, wherein the RF waveguide is on a waveguide substrate, and wherein the waveguide substrate is mounted on the integration substrate.

Example 29 includes the integrated system of Example 28, wherein the coaxial interconnect has a geometry configured to compensate for a dielectric mismatch between the chip substrate and the waveguide substrate.

Example 30 includes the integrated system of Example 27, wherein the RF waveguide is patterned on the integration substrate, and wherein the coaxial interconnect has a geometry configured to compensate for a dielectric mismatch between the chip substrate and the integration substrate.

Example 31 includes the integrated system of any one of Examples 27-30, wherein the coaxial interconnect includes a first portion having a first end coupled to the conductor and the one or more ground contact pads of the integrated circuit, a second portion having a second end coupled to the RF waveguide, and a transition portion extending between the first and second portions, the first portion having a first diameter, and the second portion having a second diameter different from the first diameter.

Example 32 includes the integrated system of Example 31, wherein the transition portion is tapered in diameter between the first diameter at a junction of the transition portion and the first portion and the second diameter at a junction of the transition portion and the second portion.

Example 33 includes the integrated system of any one of Examples 27-32, wherein the coaxial interconnect has a maximum insertion loss of 2.5 dB at an operational frequency of the integrated system.

Example 34 includes the integrated system of Example 33, wherein the length of the coaxial interconnect exceeds one millimeter.

Example 35 includes the integrated system of any one of Examples 27-34, wherein the coaxial interconnect comprises gold, copper, nickel, silver, platinum, or gold.

Example 36 includes the integrated system of any one of Examples 27-35, wherein the metal shield is a full shield, wire frame shield or slit frame shield.

Example 37 is a method of electrically connecting an integrated circuit chip to an off-chip radio frequency (RF) waveguide, the method comprising: providing an integration substrate having the integrated circuit chip and the RF waveguide mounted thereon; and printing, using an additive manufacturing apparatus, a coaxial interconnect extending between a plurality of first metal contact regions on the integrated circuit chip and a plurality of second metal contact regions on the RF waveguide, the coaxial interconnect including a metal core and a metal shield at least partially surrounding the metal core and arranged to be coaxial with the metal core.

Example 38 includes the method of Example 37, wherein printing the coaxial interconnect comprises printing the coaxial interconnect using an electrochemical 3D printing apparatus.

Example 39 includes the method of Example 37, wherein printing the coaxial interconnect comprises printing the coaxial interconnect using an aerosol jet printing apparatus.

Example 40 includes the method of Example 37, wherein printing the coaxial interconnect comprises printing the coaxial interconnect using a laser-induced molten metal printing process.

Example 41 includes the method of any one of Examples 37-40, wherein printing the coaxial interconnect comprises varying a diameter of the coaxial interconnect along a length of the coaxial interconnect to produce the coaxial interconnect having a first diameter at a first end coupled to the integrated circuit chip and a second diameter at a second end coupled to the RF waveguide, the first and second diameters being different.

Example 42 includes the method of any one of Examples 37-41, wherein the metal core and the metal shield are printed in gold, copper, nickel, platinum, silver, or aluminum.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and embodiments have been described herein. The features, aspects, and embodiments are susceptible to combination with one another as well as to variation and modification, as will be appreciated in light of this disclosure. The present disclosure should, therefore, be considered to encompass such combinations, variations, and modifications. It is intended that the scope of the present disclosure be limited not by this detailed description, but rather by the claims appended hereto. Future filed applications claiming priority to this application may claim the disclosed subject matter in a different manner and may generally include any set of one or more elements as variously disclosed or otherwise demonstrated herein.

What is claimed is:

1. An integrated system comprising:
an integration substrate;
an integrated circuit on the integration substate;
a radio frequency (RF) waveguide on the integration substrate; and
a coaxial interconnect electrically coupling the integrated circuit to the RF waveguide, the coaxial interconnect including a metal core and a metal shield at least partially surrounding the metal core along a length of the coaxial interconnect, wherein the coaxial interconnect includes a first portion coupled to the integrated circuit, a second portion coupled to the RF waveguide, and a transition portion extending between the first and second portions, the first portion having a first diameter, and the second portion having a second diameter different from the first diameter.

2. The integrated system of claim 1, wherein the coaxial interconnect has a maximum insertion loss of 2.5 dB at an operational frequency of the integrated system.

3. The integrated system of claim 1, wherein the metal core and the metal shield are made at least partially of gold.

4. The integrated system of claim 1, wherein the integrated circuit comprises a chip substrate, a conductor on a surface of the chip substrate, and one or more ground contact pads on the surface of the chip substrate;
wherein the metal core of the coaxial interconnect is coupled to the conductor; and
wherein the metal shield of the coaxial interconnect is coupled to the one or more ground contact pads.

5. The integrated system of claim 4, wherein the surface of the chip substrate is a first surface, and wherein integrated circuit further comprises:
a ground plane on a second surface of the chip substrate; and
one or more metal-filled ground vias extending through the chip substrate to electrically connect the one or more ground contact pads to the ground plane.

6. The integrated system of claim 4, wherein the RF waveguide is patterned on the integration substrate; and
wherein the first diameter of the first portion of the coaxial interconnect and the second diameter of the second portion of the coaxial interconnect are selected to compensate for a mismatch in dielectric constant between the integration substrate and the chip substrate.

7. The integrated system of claim 4, wherein the RF waveguide is patterned on a waveguide substrate;
wherein the waveguide substrate is mounted to the integration substrate; and
wherein the first diameter of the first portion of the coaxial interconnect and the second diameter of the second portion of the coaxial interconnect are selected to compensate for a mismatch in dielectric constant between the waveguide substrate and the chip substrate.

8. The integrated system of claim 7, wherein the waveguide substrate comprises alumina, and the chip substrate comprises gallium and nitrogen.

9. The integrated system of claim 1, wherein the transition portion is tapered in diameter between the first diameter at a junction of the transition portion and the first portion and the second diameter at a junction of the transition portion and the second portion.

10. The integrated system of claim 1, wherein the metal shield is a full shield, wire frame shield or slit frame shield.

11. An integrated system comprising:
an integration substrate;
an integrated circuit mounted on the integration substate, the integrated circuit comprising a chip substrate, a conductor on a first surface of the chip substrate, one or more ground contact pads on the first surface of the chip substrate, a ground plane on a second surface of the chip substrate; and one or more metal-filled ground vias extending through the chip substrate to electrically connect the one or more ground contact pads to the ground plane;
a radio frequency (RF) waveguide mounted on the integration substrate; and
a coaxial interconnect electrically coupling the integrated circuit to the RF waveguide, the coaxial interconnect comprising a metal core coupled to the conductor and a metal shield at least partially surrounding the metal core and coupled to the one or more ground contact pads.

12. The integrated system of claim 11, wherein the RF waveguide is on a waveguide substrate; and
wherein the waveguide substrate is mounted on the integration substrate.

13. The integrated system of claim 12, wherein the coaxial interconnect has a geometry configured to compensate for a dielectric mismatch between the chip substrate and the waveguide substrate.

14. The integrated system of claim 11, wherein the RF waveguide is patterned on the integration substrate; and
wherein the coaxial interconnect has a geometry configured to compensate for a dielectric mismatch between the chip substrate and the integration substrate.

15. The integrated system of claim 11, wherein the coaxial interconnect includes a first portion having a first end coupled to the conductor and the one or more ground contact pads of the integrated circuit, a second portion having a second end coupled to the RF waveguide, and a transition portion extending between the first and second portions, the first portion having a first diameter, and the second portion having a second diameter different from the first diameter.

16. The integrated system of claim 15, wherein the transition portion is tapered in diameter between the first diameter at a junction of the transition portion and the first portion and the second diameter at a junction of the transition portion and the second portion.

17. The integrated system of claim 11, wherein the coaxial interconnect has a maximum insertion loss of 2.5 dB at an operational frequency of the integrated system.

18. A method of electrically connecting an integrated circuit chip to an off-chip radio frequency (RF) waveguide, the method comprising:
providing an integration substrate having the integrated circuit chip and the RF waveguide mounted thereon; and
printing, using an additive manufacturing apparatus, a coaxial interconnect extending between a plurality of first metal contact regions on the integrated circuit chip and a plurality of second metal contact regions on the RF waveguide, the coaxial interconnect including a metal core and a metal shield at least partially surrounding the metal core and arranged to be coaxial with the metal core.

19. The method of claim 18, wherein printing the coaxial interconnect comprises printing the coaxial interconnect using an electrochemical 3D printing apparatus.

20. The method of claim 18, wherein printing the coaxial interconnect comprises varying a diameter of the coaxial interconnect along a length of the coaxial interconnect to produce the coaxial interconnect having a first diameter at a first end coupled to the integrated circuit chip and a second diameter at a second end coupled to the RF waveguide, the first and second diameters being different.
